(19) United States
(12) Patent Application Publication
(10) Pub. No.: US 2005/0287814 A1
(43) Pub. Date: Dec. 29, 2005

(54) H2O plasma for simultaneous resist removal and charge releasing

(75) Inventors: Yuan-Bang Lee, Tongxiao Town (TW); Tzu-Yang Wu, Hsinchu (TW); Sheug-Liang Pan, Hsin-Chu (TW); U. H. Lin, Taipei City (TW); Yu-Chih Lai, Jhubei City (TW); De-Fang Chen, Lujhu Township (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 11/140,115

(22) Filed: May 27, 2005

Related U.S. Application Data
(60) Provisional application No. 60/583,719, filed on Jun. 29, 2004.

(51) Int. Cl. H01L 21/00; H01L 21/302; H01L 21/26; H01L 21/461; H01L 21/324; H01L 21/42; H01L 21/477

(52) U.S. Cl. 438/710; 438/7; 438/795

(57) ABSTRACT

An in-situ method of stripping a layer of resist from a substrate or wafer utilizes pure H₂O plasma recipe to substantially prevent charges from accumulating on the substrate or wafer during stripping of the layer of resist.

### RELATED APPLICATIONS

This application claims the benefit of U.S. Provisional Application No. 60/583,719 filed on Jun. 29, 2004, the entire disclosure of which is incorporated herein by reference.

### FIELD OF INVENTION

The present invention relates to semiconductor device fabrication. More particularly, the present invention relates to a method of simultaneously removing resist and releasing charges from a wafer.

### BACKGROUND OF THE INVENTION

In semiconductor device fabrication, a photolithographically defined resist pattern layer is typically used as a mask for etching an underlying layer of a wafer. After etching, the resist layer, which may be a photoresist or e-beam resist, is usually removed in an oxygen plasma process. In this process, the wafer is positioned in a resist strip process chamber and an etch gas recipe, which includes as its main species oxygen (O₂), is then fed into the chamber. The O₂ etch gas may further include other species, such as H₂O vapor and/or a small amount of N₂. A plasma of the gas ions, which consists substantially of O₂, is formed above the wafer and removes the resist layer.

As schematically depicted in FIG. 1, there is a high tendency during the O₂ plasma-based resist removal process for O₂ radicals to capture electrons within the plasma because of their electronegative characteristics. This leads to relatively low electron density which causes spatially non-uniform distribution of the O₂ plasma. The spatially non-uniform O₂ plasma, in turn, may evoke a charge build-up on the wafer. The charge accumulation on the wafer may cause certain defects including, without limitation, pad pitting, galvanic metal corrosion, tungsten dredging, poor quality gate oxides and the like.

Accordingly, a resist removal method is needed that substantially eliminates the accumulation of charges on the wafer.

### BRIEF DESCRIPTION OF THE DRAWINGS

FIG. 1 is a drawing schematically depicting wafer surface charge accumulation cause by a prior art O₂ plasma-based resist removal method.

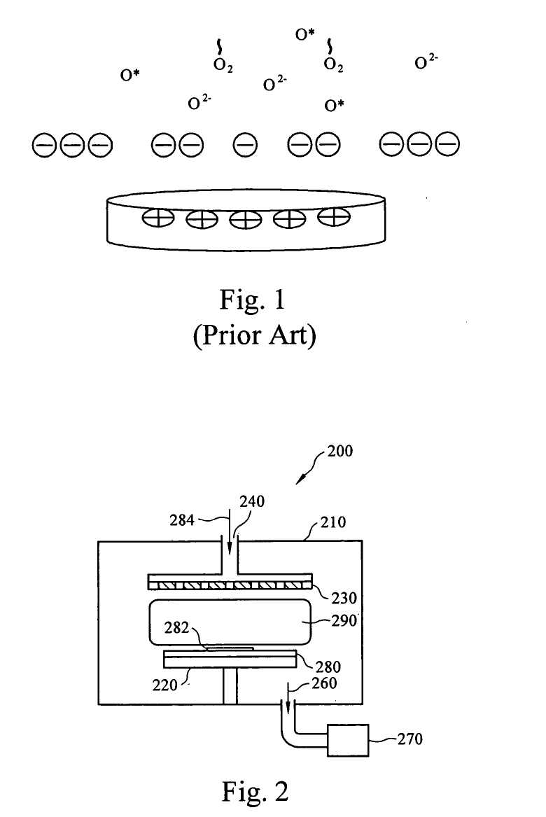

FIG. 2 is a drawing schematically depicting an exemplary plasma process chamber for performing the methods of the invention.

FIG. 3 is a flowchart showing the steps of a method of the invention.

FIG. 4 is a drawing schematically depicting wafer surface charge releasing affected by the H₂O plasma-based resist removal method of the invention.

FIGS. 5A-5C are surface charging maps of wafers after performing resist strips using a prior art O₂ plasma recipe and the H₂O plasma recipe of the present invention.

FIGS. 6A and 6B are OM (optical microscope) photographs of metal pads defined on a wafer after performing resist strips using a prior art O₂ plasma recipe.

FIGS. 7A and 7B are photographs of metal pads defined on a wafer after performing resist strips using the H₂O plasma recipe of the present invention.

FIG. 8A is a drawing schematically depicting a prior art process flow that utilizes a supplemental H₂O baking process to address tungsten dredge problems.

FIG. 8B is a drawing schematically depicting an exemplary process flow that utilizes the H₂O plasma resist stripping method of the invention to solve tungsten dredge problems.

FIG. 9A is a typical surface charging map of a wafer before de-charging.

FIG. 9B is a surface charging map of a wafer after performing a supplemental prior art in-situ H₂O baking process on the wafer.

FIG. 9C is a surface charging map of a wafer after performing an in-situ H₂O plasma de-charging process on the wafer.

### DETAILED DESCRIPTION

The present invention comprises, in one aspect, an in-situ method of removing a layer of resist from a substrate or wafer without substantially accumulating charges on the substrate or wafer. In one embodiment, the method utilizes a pure H₂O plasma recipe to substantially prevent charges (e.g., positive) from accumulating on the substrate or wafer during removal of the layer of resist. The use of the pure H₂O plasma recipe during the stripping process suppresses charge accumulation and charge enhanced electro-chemical problems including, without limitation, pad pitting, galvanic metal corrosion, tungsten dredging, poor quality gate oxides and other known electro-chemical problems.

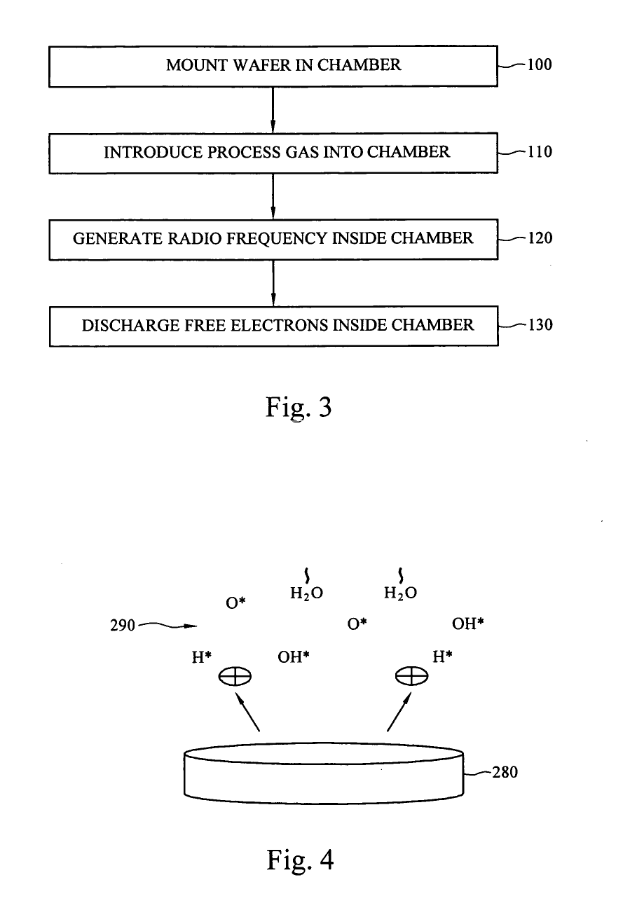

The method is performed in a plasma process chamber, such as a conventional resist strip chamber, a plasma etch reactor, or other suitable plasma process chamber. FIG. 2 schematically depicts an exemplary plasma process chamber 200 that may used in the method. The plasma process chamber includes a housing 210 that defines the plasma process chamber 200. A wafer platform 220 is provided inside the chamber 200. The substrate or wafer to be processed is mounted on the wafer platform 220. A showerhead-shape gas inlet nozzle 230 is disposed above the wafer platform 220. Reaction gases are routed into the chamber 200 via a gas inlet 240, which communicates with the inlet nozzle 230. An exhaust outlet 260 connected to a vacuum pump 270 is used to evacuate the process chamber 200. Electric field generating means (not shown) are used to generate an electric field in the chamber 200 of a sufficient magnitude such that a process fluid flowing in the chamber 200, breaks down and becomes ionized. The plasma is initiated by releasing or discharging free electrons inside the chamber 200 using, for example, field emission from a negatively biased electrode within the chamber 200. In one embodiment, the electric field used for generating the water plasma may be in the microwave frequency range. The power of such a microwave electric field may range between about 100 watts and about 10,000 watts.

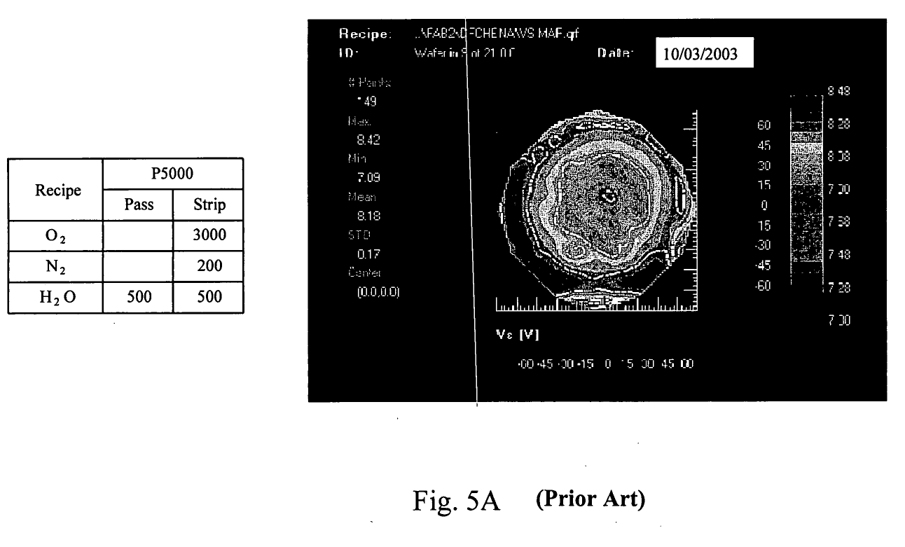

Referring to FIG. 2 and the flowchart of FIG. 3, the method commences in step 100 with the mounting of a substrate or wafer 280 on the wafer platform 220 inside the plasma process chamber 200. The substrate or wafer 280 may be composed of a semiconductor material, such as silicon. The substrate or wafer 280 includes a layer of resist formed thereon 282. The resist layer 282 may comprise, for example, a photoresist or an e-beam resist. The resist layer 282 may be at least partially disposed on a metal layer of the substrate or wafer 280 or at least partially disposed on a dielectric layer of the substrate or wafer 280 (the dielectric layer may be at least partially disposed on a metal layer of the substrate or wafer 280). The metal layer may comprise, for example, an aluminum or tungsten-based metal nitride. The dielectric layer may comprise silicon oxynitride or some other dielectric material. Typically, the substrate or wafer 280 has just completed an etching process wherein the underlying metal or dielectric layer has been patterned using the resist layer as a mask.

In step 110, a process gases containing one or more chemical species 284 is introduced under pressure into the plasma process chamber 200, via the gas inlet 240 and inlet nozzle 230. The one or more chemical species are ionized by the electric field generated within the chamber. The one or more chemical species may comprise H₂O, argon (Ar), helium (He), fluorine based species and combinations thereof. Of these species, the H₂O and fluorine-based species, and any combinations thereof comprise reactive species. The Ar, He and any combinations thereof are non-reactive species. No O₂ and/or N₂ species is/are used in the invention to avoid charge accumulation. The pressure (partial pressure) exerted by the process gas inside the plasma process chamber 200 before initiating a plasma is adjusted to a value ranging between about 70 percent and 100 percent of the total pressure exerted by the gas 284.

In step 120, an electric field is generated inside the chamber 200 by the electric field generating means.

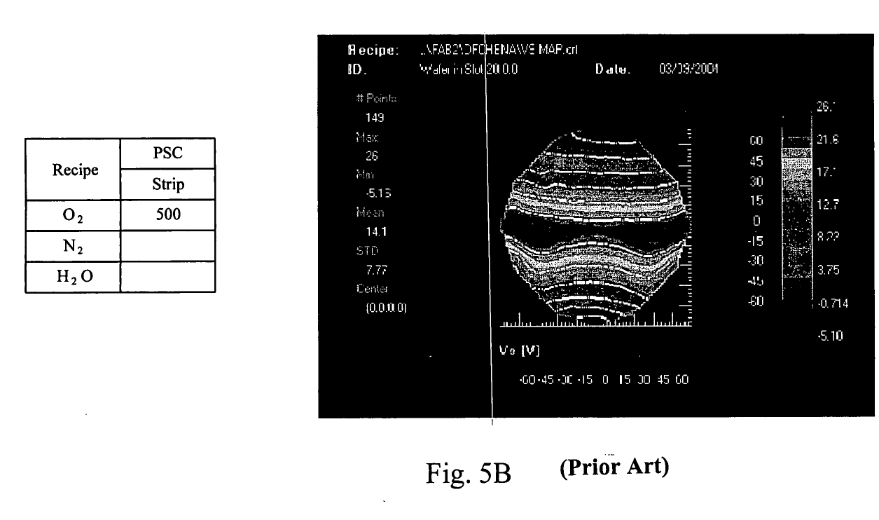

In step 130, free electrons are discharged inside the plasma process chamber 200 and travel through the process gas to generate a pure H₂O plasma 290 in the chamber 200. As the H₂O plasma stabilizes, the pressure exerted by the gas 284 inside the plasma process chamber 200 is adjusted to be between about 0.1 Torr and 10 Torr. As schematically depicted in FIG. 4, the H₂O plasma 290 removes or strips the layer 282 of resist from the substrate or wafer 280 without substantially accumulating charges on the substrate or wafer 280.

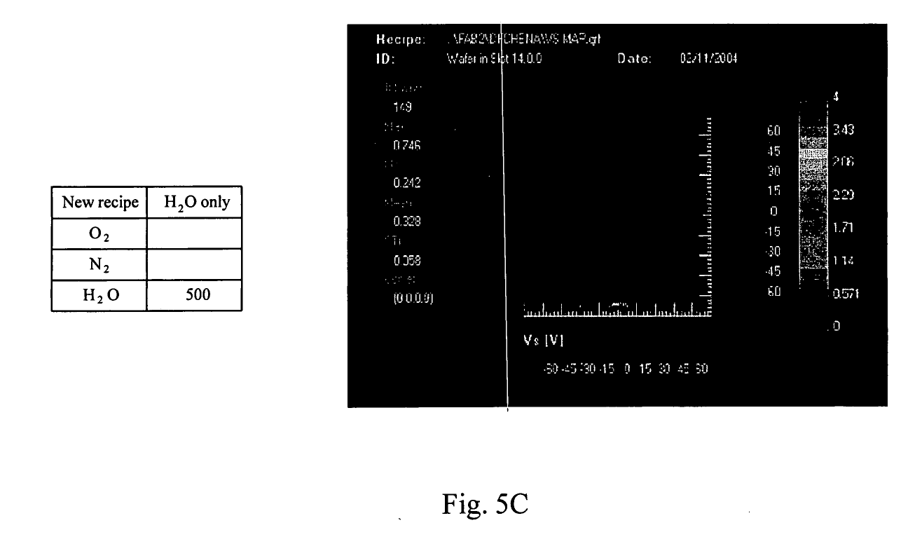

FIGS. 5A-5C are surface charging maps of wafers after performing resist strips on bare silicon wafers (no resist coatings) using a prior art O₂ plasma recipe and the H₂O plasma recipe of the present invention. The surface charging maps compare the decharging ability of the prior art method to the decharging ability of the method of the present invention. More specifically, FIG. 5A is a surface charging map of a first wafer after performing a resist strip process for 80 seconds with a first prior art O₂ plasma plasma recipe comprising an O₂ flow rate of 5000 sccm (standard cubic centimeters per minute), an N₂ flow rate of 200 sccm and a H₂O flow rate of 500 sccm. The first wafer had a mean surface charging of 8.18 volts with a standard deviation of 0.17 volts. FIG. 5B is a surface charging map of a second wafer after performing a resist strip process for 120 seconds with a second prior art O₂ plasma recipe comprising an O₂ flow rate of 500 sccm. The second wafer had a mean surface charging of 14.1 volts with a standard deviation of 7.77 volts. FIG. 5C is a surface charging map of a third wafer after performing a resist strip for 130 seconds using a H₂O plasma recipe of the present invention comprising a H₂O flow rate of 500 sccm. The third wafer had a mean surface charging of 0.328 volts with a standard deviation of 0.058 volts.

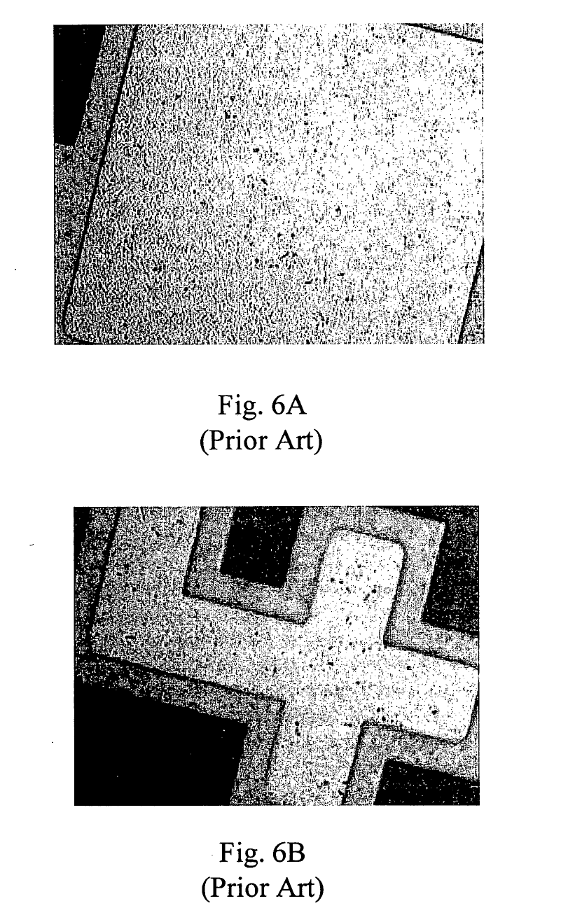

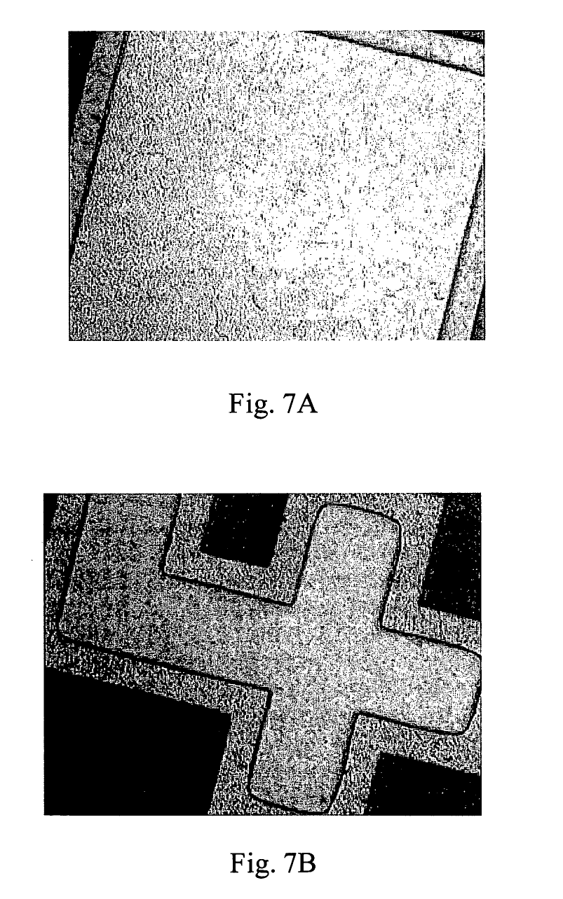

FIGS. 6A-B and 7A-B are OM (optical microscope) photographs of metal pads defined on wafers after performing resist strips using the prior art O₂ plasma recipe and the H₂O plasma recipe of the present invention. The OM photographs of FIGS. 6A and 6B show metal pads after performing a resist strip using the prior art O₂ plasma recipe. As can be seen, the metal pads suffered severe pad pitting after resist stripping using the O₂ plasma recipe. The photographs of FIGS. 7A and 7B show metal pads after performing a resist strip using the H₂O plasma recipe of the present invention. As can be seen, the metal pads had virtually no pad pitting after resist stripping using the H₂O plasma recipe, which neutralizes and/or releases charges during resist stripping process.

After resist stripping, wafers of certain products have a queue time of about 20 minutes. Severe galvanic metal corrosion of the top metal has been found in the wafers of these products after resist stripping using the prior art O₂ plasma recipe. It is believed that the severity of the corrosion is due to cumulative positive charging that occurs with these products, which accelerates galvanic metal corrosion. The pure H₂O plasma recipe of the present invention substantially solves this metal galvanic corrosion problem because it extends the corrosion window to about four (4) hours. This in turn, allows the queue window to be extended. It should be noted that the addition of O₂ and/or N₂ to the H₂O plasma recipe considerably reduced the corrosion window to about 20 minutes. It is believed that the addition of the O₂ and/or N₂ to the H₂O plasma recipe induced positive charging, which worsened the galvanic metal corrosion.

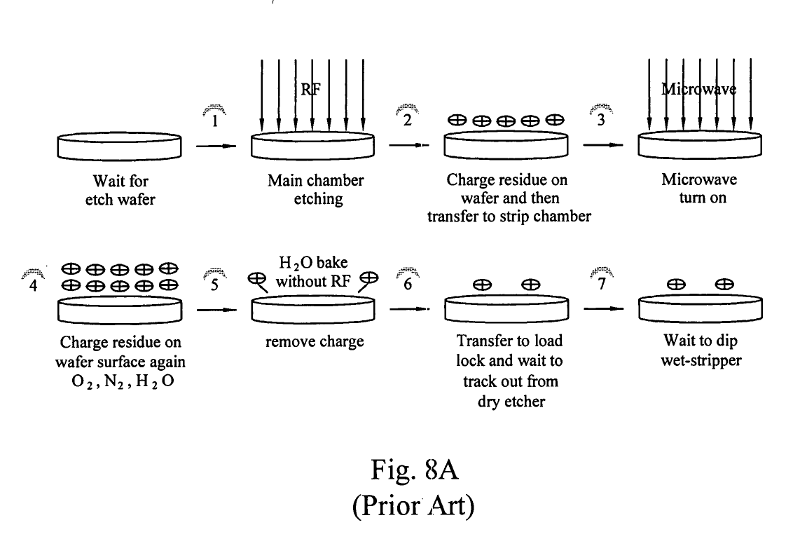

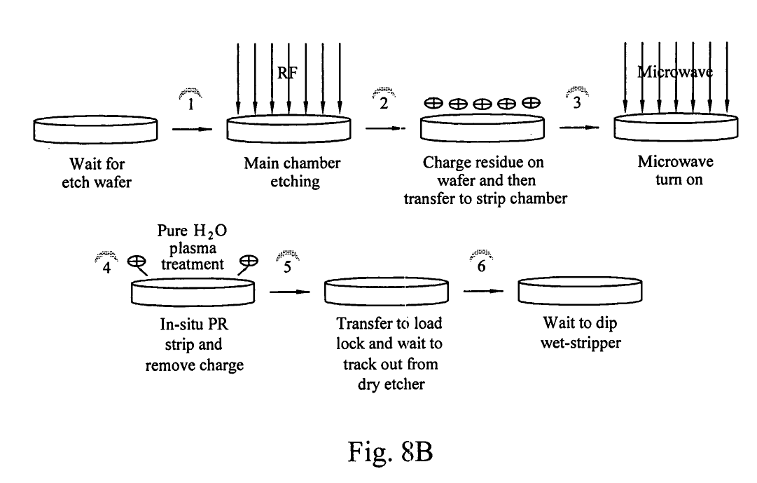

With the advent of sub-micron size technology, reduced overlap tolerance between the metal lines and metal (e.g., tungsten) filled vias evokes several technical difficulties. Charge induced corrosion (dredge) of the tungsten which plugs the vias is one of the problems. Replacing the O₂ plasma recipe with the pure H₂O plasma recipe of the invention in the stripping process substantially solves tungsten dredge problems. As depicted in prior art process flow of FIG. 8A, a supplemental H₂O baking process (without RF) is currently used to address the tungsten dredge problem. However, some charge residue remains on the wafer surface after the supplemental H₂O baking process. The use of the H₂O plasma recipe eliminates the need for the supplemental H₂O baking process as depicted in the process flow of FIG. 8B, and substantially removes the charge residue on the wafer surface.

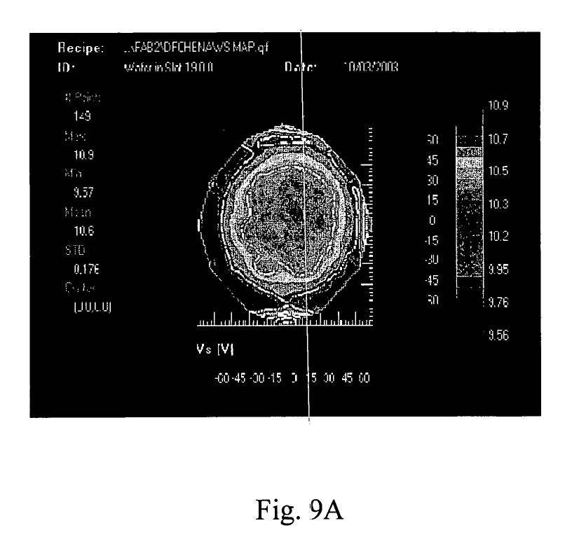

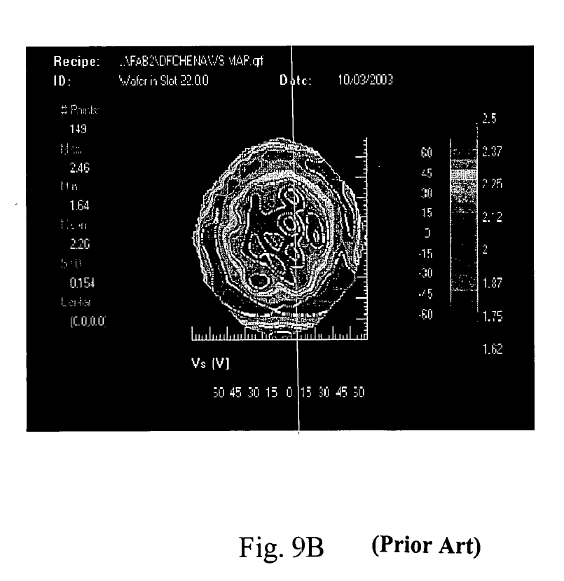

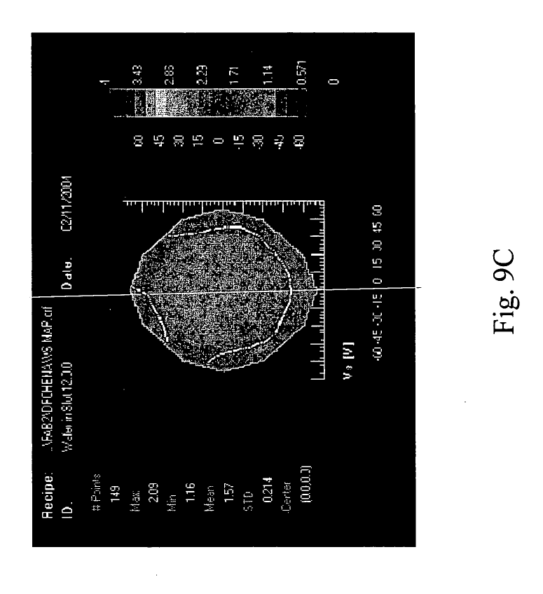

Another aspect of the present invention comprises a de-charging process utilizing the H₂O plasma recipe described above. In this aspect of the invention, the H₂O plasma may be utilize to remove any charges from the substrate. The H₂O plasma de-charging process has greater de-charging capability than supplemental prior art H₂O baking processes. This can be seen by referring to the surface charging maps shown in FIGS. 9A-9C. FIG. 9A is a typical surface charging map of a wafer before de-charging. The wafer, before de-charging, had a mean surface charging of 10.6 volts with a standard deviation of 0.176 volts. FIG. 9B is a surface charging map of a wafer after performing a supplemental prior art in-situ H₂O baking process on the wafer for 50 seconds without RF. The wafer had a mean surface charging of 2.26 volts with a standard deviation of 0.154 volts after prior art de-charging. FIG. 9C is a surface charging map of a wafer after performing an in-situ H₂O plasma de-charging process on the wafer for 130 seconds. The wafer had a mean surface charging of 1.57 volts with a standard deviation of 0.214 volts after de-charging with the H₂O plasma.

While the foregoing invention has been described with reference to the above, various modifications and changes can be made without departing from the spirit of the invention. Accordingly, all such modifications and changes are considered to be within the scope of the appended claims.

1. A method of making a semiconductor device, the method comprising the steps of:
providing a substrate including a layer of resist formed thereon;
placing the substrate in a process chamber;
introducing a gas into the process chamber, the gas having a pressure and comprising an H2O reactive species having a partial pressure of at least about 70 percent; and
discharging free electrons in the process chamber to form a plasma therein.

2. The method according to claim 1, further comprising the step of adjusting the pressure of the gas to a value between about 0.1 Torr and about 10 Torr.

3. (canceled)

4. (canceled)

5. The method according to claim 1, wherein the substrate further includes a metal layer, the layer of resist disposed at least partially on the metal layer.

6. (canceled)

7. The method according to claim 1, wherein the substrate further includes a metal layer and a dielectric layer at least partially disposed on the metal layer, the layer of resist at least partially disposed on the dielectric layer.

8. (canceled)

9. The method according to claim 1, wherein the substrate is composed of a semiconductor material.

10. The method according to claim 1, wherein the gas further comprises a non-reactive species.

11. The method according to claim 10, wherein the non-reactive species is selected from the group consisting of Ar, He, and any combinations thereof.

12. The method according to claim 11, wherein the gas further comprises a fluorine-based reactive species.

13. The method according to claim 1, wherein the gas further comprises a fluorine-based reactive species.

14. A method of simultaneously removing a layer of resist from a substrate and de-charging or preventing charging of the substrate, the method comprising the steps of:
placing the substrate in a process chamber;
introducing a gas into the process chamber, the gas having a pressure and comprising an H2O reactive species having a partial pressure of at least about 70 percent; and
discharging free electrons in the process chamber to form a plasma therein.

15. The method according to claim 14, further comprising the step of adjusting the pressure of the fluid to a value between about 0.1 Torr and about 10 Torr.

16. (canceled)

17. (canceled)

18. The method according to claim 14, wherein the substrate further includes a metal layer, the layer of resist disposed at least partially on the metal layer.

19. (canceled)

20. The method according to claim 14, wherein the substrate further includes a metal layer and a dielectric layer at least partially disposed on the metal layer, the layer of resist at least partially disposed on the dielectric layer.

21. The method according to claim 20, wherein the metal layer comprises an aluminum- or tungsten-based metal nitride and the dielectric layer comprises silicon oxynitride.

22. The method according to claim 14, wherein the substrate is composed of a semiconductor material.

23. The method according to claim 14, wherein the gas further comprises a non-reactive species.

24. The method according to claim 23, wherein the non-reactive species is selected from the group consisting of Ar, He, and any combinations thereof.

25. The method according to claim 24, wherein the gas further comprises a fluorine-based reactive species.

26. The method according to claim 14, wherein the gas further comprises a fluorine-based reactive species.

27. A method of de-charging a charged substrate, the method comprising the steps of:
placing the substrate in a process chamber;
introducing a gas into the process chamber, the gas having a pressure and comprising an H2O reactive species having a partial pressure of at least about 70 percent; and
discharging free electrons in the process chamber to form a plasma therein.

28. (canceled)
